(19) United States
(12) Patent Application Publication
(10) Pub. No.: US 2024/0097385 A1
(43) Pub. Date: Mar. 21, 2024

(54) RF CONNECTOR ASSEMBLY, MEASUREMENT APPLICATION DEVICE AND METHOD FOR MANUFACTURING A RF CONNECTOR ASSEMBLY

(71) Applicant: ROHDE & SCHWARZ GMBH & CO. KG, München (DE)

(72) Inventor: Franz STRASSER, Niclasreuth (DE)

(21) Appl. No.: 17/934,063

(22) Filed: Sep. 21, 2022

(51) Int. Cl. H01R 24/50

(52) U.S. Cl. CPC H01R 24/50; H01R 2103/00

(57) ABSTRACT

The present disclosure provides a RF connector assembly comprising: a coaxial RF connector, whereas the coaxial RF connector comprises an axially arranged inner conductor and a tubular outer conductor radially enclosing the inner conductor in axial direction, a printed circuit board unit to which the coaxial RF connector is electrically connected for transmitting signals between the coaxial RF connector and a printed circuit board comprised the printed circuit board unit, a trace of the printed circuit board to which the inner conductor is electrically connected and a grounded element comprised by the printed circuit board unit to which the outer conductor is electrically connected.

### TECHNICAL FIELD

The disclosure relates to a RF connector assembly, a measurement application device utilizing such RF connector assembly and a method for manufacturing a RF connector assembly.

### BACKGROUND

The disclosed teaching is applicable to any type of RF connector assemblies comprising a coaxial RF connector and a printed circuit board to which the coaxial RF connector is connected. RF is in this context the abbreviation for radio frequency. The RF connector assembly can be especially used for measurement application devices e.g., oscilloscopes or signal generators.

For measurement application devices, e.g., like oscilloscopes, it is of importance that these are configured such that uncertainties regarding measurement application results caused by the measurement application device are reduced as much as possible.

This means, besides others, an electrical connection fulfilling certain electric criteria needs to be established between a printed circuit board of a measurement application device and a coaxial RF connector exchanging signals for measurement application purposes.

A coaxial RF connector is a coaxial electrical connector configured to transmit radio frequencies in the multi-Megahertz (abbreviated as MHz) up to multi-Gigahertz (abbreviated as GHz) range. Coaxial RF connectors are typically used with coaxial cables and are configured to maintain the shielding that the coaxial design offers.

Such shielding of the coaxial RF connector is realized by a grounded outer connector concentrically arranged around an inner conductor. The outer conductor shields the inner conductor from electromagnetic disturbances but also avoids the transmission of electromagnetic signals from the inner conductor to the environment.

This shielding concept applies for the coaxial cable as well as for a coaxial RF connector. In case the coaxial RF connector is connected to a printed circuit board, e.g., of a measurement application device, also the printed circuit board comprises a plurality of differed grounded elements to shield the desired signal processing on the printed circuit board, but also a housing of the printed circuit board is typically grounded.

Especially for measurement applications a change in the transmission line impedance at the connection between a coaxial RF connector and a trace of a printed circuit board, which typically has a planar and no coaxial conductor structure, is of importance. Such changes of impedance in the transmission line should be avoided as otherwise undesired signal reflection and power loss occurs. For this reason, a controlled impedance is required.

As the frequency increases, especially for high frequency applications, transmission line effects become more and more important. Also, small impedance variations along the transmission line can cause signals to (partially) reflect rather than pass through. This leads to failures and inaccuracies, especially in high frequency measurement applications. In this context the coaxial RF connector and the connection to a printed circuit board, especially of the electrically grounded structures typically carrying the reverse current, is of special importance.

Accordingly, there is a need for further improved RF connector assemblies and respective measurement application devices.

### SUMMARY

Such an improved RF connector assembly and measurement application device is provided by the features of the independent claims. It is understood that independent claims of a claim category may be formed in analogy to the dependent claims of another claim category.

Accordingly, it is provided: A RF connector assembly comprising: a coaxial RF connector, whereas the coaxial RF connector comprises an axially arranged inner conductor and a tubular outer conductor radially enclosing the inner conductor in axial direction, a printed circuit board unit comprising a printed circuit board to which the coaxial RF connector is electrically connected for transmitting signals between the coaxial RF connector and a printed circuit board, a trace of the printed circuit board to which the inner conductor is electrically connected and a grounded element comprised by the printed circuit board unit to which the outer conductor is electrically connected, an electrically conductive foam element arranged radially between the inner conductor and the outer conductor, whereas the electrically conductive foam element extends, especially protrudes the outer conductor, in axial direction towards the grounded element, whereas the electrically conductive foam element is configured such that it electrically connects the outer conductor and the grounded element and is electrically isolated from the inner conductor.

Further, it is provided: A measurement application device, especially an oscilloscope or signal generator, comprising at least one RF connector assembly according to any one of the embodiments provided in this disclosure. Such measurement application device is suitable to provide low-frequency and high frequency measurement applications utilizing the same RF connector assembly. Such measurement application device can comprise any combination of features of the RF connector assembly described above.

Further, it is provided a method for manufacturing a RF connector assembly according to any one of the embodiments provided in the present disclosure. The method comprising the steps of:
arranging by press-fitting an compressible, electrically conductive foam element of hollow-cylindric shape in a cylindric volume defined by a tubular formed outer conductor of a coaxial RF connector such that the electrically conductive foam element electrically contacts the outer conductor and is fixed by a radial pressure force on the outer conductor in the volume, whereas the electrically conductive foam element is further arranged such that it protrudes the outer conductor in axial direction and the electrically conductive foam is isolated from an inner conductor comprised by the coaxial RF conductor,
creating a contact force or contact pressure between a front side of the electrically conductive foam element, which is oriented towards an essentially planar grounded element of a printed circuit board unit and the essentially planar grounded element of the printed circuit board unit, whereas the front side and the essentially planar grounded element are arranged essentially co-planar,
fixing the coaxial RF connector relative to the printed circuit board unit in a position in which at least a specified minimum contact force or contact pressure between the front side and the planar grounded element of the printed circuit board unit is reached.

The inventors recognized that for RF measurement applications, especially at high frequencies, e.g., in the range of 12 to 16 GHz, it is of importance to provide low inductivity for the incoming current and a low inductivity for the reverse current in the coaxial RF connector. In addition, the impedance needs to be controlled to avoid undesired signal reflections. Further, for low frequency measurement applications, e.g., 50 MHz to 500 MHz, a low-ohmic connection needs to be provided for measurement application purposes.

The reverse current flows on the grounded voltage level. For the reverse current a low-ohmic connection for low frequencies can be achieved by an additional current path on the grounded level. Considering this, it remains the challenge to provide for high frequency applications low inductivity and a controlled impedance for the reverse current to enable a coaxial RF connector assembly which allows to process low-frequency and high frequency signals. Also undefined connector gaps between the coaxial RF connector and the grounded elements of the printed circuit board unit, due to present technical tolerances between the coaxial RF connector and grounded element of the printed circuit board unit, can cause challenges, especially with regard to the transmittable bandwidth.

These problems were addressed and solved by the inventors by providing the teaching according to claim 1, especially by providing an electrically conductive foam element, which is radially arranged between the inner conductor and the outer conductor, whereas the electrically conductive foam element extends in axial direction towards the grounded element, whereas the electrically conductive foam element is configured such that it electrically connects the outer conductor and the grounded element and is electrically isolated from the inner conductor.

The axial direction is the direction along the axis which is typically the center axis of the inner conductor of the coaxial RF connector but also the center axis of the outer conductor.

The printed circuit board unit comprises the printed circuit board with its electrical elements. In addition, the printed circuit board unit comprises further functional elements that are not directly associated with the printed circuit board, e.g., the housing of the printed circuit board, which are electrically coupled and functionally assigned to the printed circuit board.

The grounded element can be comprised by the printed circuit board itself, which is comprised by the printed circuit board unit. The grounded element can also be part of the printed circuit board unit, but not comprised by the printed circuit board itself, e.g., the housing of the printed circuit board.

It is sufficient, but not necessary, that only one grounded element of the printed circuit board unit is contact by the electrically conductive foam element. A grounded element can therefore be understood as at least one grounded element.

Also, a plurality of grounded elements comprised by the printed circuit board unit can be utilized for contacting the electrically conductive foam element. Especially the plurality of the grounded elements can be selected from the group of at least one grounded element of the printed circuit board and at least one grounded element of the printed circuit board unit, which is not comprised by the printed circuit board, e.g., the housing of the printed circuit board.

The electrically conductive foam element is electrically conductive and can be especially made of the same material as the grounded element and/or the outer conductor. This avoids contact voltages between different materials of the electrically conductive foam element and the outer conductor, respectively, between the grounded element of the printed circuit board unit, e.g., the grounded housing or other grounded electrical elements of the printed circuit board or the printed circuit board unit, and the electrically conductive foam element. The electrically conductive foam element can be especially a metal foam, e.g., aluminum foam.

A metal foam is a structure comprising a solid metal with gas-filled pores, whereas the gas-filled pores comprise a large portion of the volume. The pores can be sealed, so-called closed-cell foam, or interconnected, so-called open-cell foam. A metal foam typically has a high porosity meaning typically 5 to 25% of the volume is made of the metal.

The electrically conductive foam element can be mounted on the coaxial RF connector side, e.g., by press fitting, or on the printed circuit board unit side, e.g., by methods used for surface mounted device (SMD), especially soldering.

However, a mounting on the coaxial RF connector side, e.g., by press fitting into the, especially cylindric, volume defined by the outer conductor, is considered advantageous as such arrangement is mechanically more stable connection than SMD connections of the electrically conductive foam element on the printed circuit board unit side.

A RF connector assembly according to claim 1 provides a low inductivity and a controlled impedance for high frequency measurement applications. This means this assembly can be used for high frequency and low frequency measurement applications. Therefore, no separate RF connector assemblies are required for such task, reducing the complexity and costs of a respective measurement application device utilizing such RF connector assembly.

In addition, the electrically conductive foam element is suitable to bridge any undefined mechanical connector gaps caused by technical, respectively mechanical, connector tolerances. This means a RF connector assembly according to claim 1 is reliable in terms of technical tolerances due to the fact that different mechanical connector settings can be compensated by the electrically conductive foam element.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to the RF connector assembly can be combined in all variations with each other and the disclosure of the description is not limited to the claim dependencies as specified in the claim set.

In an embodiment, which can be combined with all other embodiments of the RF connector assembly mentioned above or below, the electrically conductive foam element may comprise a first part comprising an opening in plane perpendicular to the axial direction, through which the inner conductor is guided in axial direction, and a second part comprising electrically conductive foam, whereas the opening is configured such that the electrically conductive foam is arranged radially distant from the inner conductor.

By arranging the electrically conductive foam distant from the inner conductor an effective electric isolation of the inner conductor from the electrically conducting foam is given. A radial distance can be provided via an air gap or other, especially solid, electrically isolating material.

The opening of the electrically conductive foam element, i.e., the first part of the electrically conductive foam element, is used to feed the inner conductor of the coaxial RF connector to the printed circuit board in an easy way. The opening can be of any shape, e.g., rectangular, quadratic, elliptic, etc.

It can be advantageous that the opening is of a symmetrical shape. Considering the coaxial arrangement of the coaxial RF connector, especially a circular shape of the opening can be advantageous. An opening of circular shape can be easily produced and allows an equal radial distance of the electrically conductive foam element to the inner conductor. This also unifies the capacitive properties of the arrangement in a plane perpendicular to the center axis.

Especially, the electrically conductive foam element can comprise as first part a circular opening through which the inner conductor is guided in axial direction, whereas a radius of the opening is larger than the outer radius of the inner conductor, whereas the opening and the inner conductor are arranged concentrically. Being arranged concentrically means that that the opening and the inner conductor have essentially the same center axis. This is an easy and cheap way of isolating the inner conductor from the electrically conductive foam.

By providing a circular opening that is of a radius, respectively diameter, larger than the radius, respectively diameter, of the inner conductor, an air gap can be easily utilized to isolate the electrically conductive foam element from the inner conductor. The inner radius of the opening and the outer radius of the inner conductor are configured such that the electrically conductive foam element and the inner conductor are not in touch, i.e., radially distanced.

In an alternative, also an electrically isolating solid material can be used as isolator between the inner conductor and the electrically conductive foam element, whereas the electrically isolating solid material is arranged radially between the inner conductor and the electrically conductive foam element.

In this case, the electrically isolating solid material is part of the second part of the electrically conductive foam element. In such case, the opening through which the inner conductor is fed can be shaped by the electrically isolating solid material. Also, a combination of electrically isolating solid material and an air gap can be used to electrically isolate the inner conductor from the conductive part of the electrically conductive foam element.

Electrically isolating solid material shall be understood as material with electrically isolating properties having a tangible physical shape at room temperature in contrast to electrically isolating materials without tangible physical shape at room temperature, e.g., like gases, especially air.

In a further embodiment of the RF connector assembly, which can be combined with all other embodiments of the RF connector assembly mentioned above or below, the electrically conductive foam element may be compressible in axial direction and/or radial direction, especially elastically compressible. Such an electrically conductive foam element is specifically advantageous for creating defined contact settings.

In case of radial and axial, especially elastic, compressibility, technical tolerances within the coaxial RF connector, but also between the coaxial RF connector and the at least one grounded element can be especially compensated in an effective way.

The compressible deformation of the electrically conductive foam element can be of plastic or of elastic nature. In both versions the connector gap can be bridged reliably between the outer conductor and the grounded element of the printed circuit board unit.

In case the deformation of the electrically conductive foam element is of plastic nature, the compressed electrically conductive foam element is in the installed state specifically adapted to the specific RF connector assembly. As the deformation of the electrically conductive foam element is plastically it will typically not fit to another RF connector assembly having other technical tolerances.

In case of elastic compressibility of the electrically conductive foam element the deformation is reversable. Therefore, the electrically conductive foam element can be used for other RF connector assemblies which might have different technical tolerance conditions.

In this context of compressibility of the electrically conductive foam element it can be advantageous, if the electrically conductive foam element extends beyond the outer conductor in axial direction, respectively protrudes the outer conductor in axial direction.

It can be further advantageous, if the electrically conductive foam element is of a radial dimension that is larger than an inner radius of the outer conductor, however, can be compressed to radial dimension smaller or identical to the inner radius of the outer conductor. This allows a, especially reversable, press-fitting of the electrically conducting foam element.

Such compressibility, especially in axial direction, of the electrically conductive foam element is preferably given in a range of usual contact forces applied between a coaxial RF connector and a printed circuit board unit, respectively printed circuit board, especially to a grounded element of the printed circuit board unit, especially of the printed circuit board.

In an embodiment of the RF connector assembly, which can be combined with all other embodiments of the RF connector assembly mentioned above or below, the electrically conductive foam element is of a hollow-cylindric shape providing, in radial direction, the opening and a cylinder wall comprising, especially consisting of, electrically conductive foam, whereas the electrically conductive foam, especially comprised by a surface of the wall directed to the outer conductor, electrically contacts the outer conductor. This provides an easy way of an electrical connection.

Such electric connection can especially be provided by a contact of the radially inner surface of the outer conductor with the electrically conductive foam comprised by the outer surface of the cylinder wall. This is especially of advantage in case of a press-fitting connection of the electrically conductive foam element into the volume defined by the outer conductor, as the press fitting creates a reliable mechanical connection and a reliable electric connection between the electric foam of the cylinder wall and the inner surface of the outer conductor.

The hollow-cylindric shape of the electrically conductive foam element is an advantageous shape for the electrically conductive foam element in terms of manufacturing. Dependent on the extension of hollow-cylindric shape the in axial direction, the hollow-cylindric shape can be also considered a hollow-disc-like shape, e.g., if the extension, i.e., the length, of the electrically conductive foam element in axial direction is smaller, especially significantly smaller, than the outer diameter of the hollow-cylindric shape of the electrically conductive foam element.

The cylinder wall of the hollow-cylindric shaped electrically conductive foam element is in a preferred embodiment entirely electrically conducting, whereas the hollow part of the electrically conductive foam element forms the opening isolating the conductive part of electrically conductive foam element from the inner conductor. The wall of the hollow-cylindric electrically conductive foam element can have variable thickness. Especially the thickness of the cylinder wall, which is the outer radius of the hollow-cylinder minus the radius of the opening, can be larger than the radius of the opening.

In an embodiment of the RF connector assembly, which can be combined with all other embodiments of the RF connector assembly mentioned above or below, the cylinder wall may have a radial thickness smaller than 0.9 times (inner radius of the outer conductor minus outer radius of the inner conductor) but at least 0.2 times (inner radius of the outer conductor minus outer radius of the inner conductor). The inner radius of the outer conductor minus outer radius of the inner conductor corresponds to the radial distance between the radially outer surface of the inner conductor and the radially inner surface of the outer conductor. With such dimension of the thickness of the cylinder wall, especially entirely consisting of electrically conductive metal foam, a sufficiently low inductivity and a controlled impedance for the reverse current on ground potential can be reached.

Furthermore, such dimensions allow a reliable electrical and mechanical bridging of the gap between the outer conductor and the grounded element. In this context, it can be sufficient that the electrically conductive foam element protrudes the outer conductor in axial direction by 0.01 to 0.5 times the outer radius of the electrically conductive foam element.

It can be advantageous if the outer radius of the hollow-cylindric electrically conductive foam element is configured such that a surface, consisting of electrically conductive foam, of the cylinder wall directed to the outer conductor electrically connects in circumferential and axial direction the surface of the outer conductor directed towards the hollow-cylindric electrically conductive foam element, i.e., the radially inner surface of the outer conductor. In this case a stable electrically contact is made between the wall of the hollow-cylindric electrically conductive foam element with the outer conductor in axial direction.

In a further embodiment, which can be combined with all other embodiments of the RF connector assembly mentioned above or below, the electrically conductive foam element electrically contacts the grounded element with a front side of the hollow-cylindric shaped electrically conductive foam element, which front side is oriented towards the grounded element. The front side is especially arranged in axial direction closer to the grounded element than the outer conductor. This is an easy and direct way of providing an electrical connection between the outer conductor and the at least one grounded element via the electrically conductive foam element.

According to this embodiment the electrically conductive foam element protrudes the outer conductor in axial direction towards the at least one grounded element of the printed circuit board unit and directly contacts the at least one grounded element. Such front-side of the hollow-cylindric shaped electrically conductive foam element can be preferably planar and perpendicular to the center axis of the inner conductor, respectively essentially co-planar to a planar surface of a grounded element which shall be contacted by the front side. Also, in this case the electrically conductive foam element can be preferably compressible.

In a further embodiment, which can be combined with all other embodiments of the RF connector assembly mentioned above or below, the electrically conductive foam element may comprise a protruding part which is arranged in axial direction between the outer conductor and the grounded element. This means the respective protruding part of the electrically conductive foam element has at least in a section between the outer conductor and the grounded element a radius that is larger than the inner radius of the outer conductor. Especially, the radius can be constant over the whole length of the protruding part and correspond to the outer radius of the outer conductor.

Such configuration of the electrically conductive foam element can be used to create an insertions stopper function for the electrically conductive foam element into the volume defined by the outer conductor. It therefore defines at the same time the length of the protruding part extending beyond the outer conductor in axial direction for bridging a connector gap and an insertion part of the electrically conducting foam element which is inserted into the volume defined by the outer conductor. The length of the protruding part of the electrically conductive foam element should be configured such that it compensates reliably all technical tolerances accepted for such RF connector assemblies between a coaxial RF connector and the printed circuit board.

In a special embodiment, the hollow-cylindric shape can have two sections with differing radius. In a first section, especially the section which shall be inserted radially between the inner conductor and the outer conductor, can be of an outer radius that is identical or slightly larger than the inner radius of the outer conductor. This allows that the respective section of the hollow-cylindric electrically conductive foam element can be inserted between the inner conductor and the outer conductor. Especially in case of a radius slightly larger than the inner radius of the outer conductor the insertion part of the electrically conductive foam element is fixed by radial pressure forces. The second section of the electrically conductive foam element, which is the protruding part, can be of an outer radius corresponding to the outer radius of the outer conductor. In between the insertion part and the protruding part of the hollow-cylindric electrically conductive foam element a transition section can be present, in which the outer radius can change abruptly, continuously or in other way from the radius of the first section, i.e., the insertion part, to the radius of the second section, i.e., the protruding part. An abrupt change shall mean that essentially a direct step from the outer radius of the insertion part to the outer radius of the protruding part is provided.

By such configuration an easy insertion stop for the electrically conductive foam element can be created allowing an easy and reliable mechanical arrangement of the electrically conductive foam element relative to the coaxial RF connector and to the printed circuit board unit.

It is advantageous, if in such an embodiment the radius of the opening of the electrically conductive foam element remains constant for the insertion part and the protruding part of the hollow-cylindric electrically conductive foam element, i.e., the opening radius is the same in the insertion part and the protruding part and for any given transition section between the insertion part and the protruding part.

In a further embodiment, which can be combined with all other embodiments of the RF connector assembly mentioned above or below, the grounded element may comprise a planar metal surface section with a surface section opening, whereas the inner conductor is guided through that surface section opening to the trace and is electrically isolated from the metal surface, whereas the front side of the hollow-cylindrically shaped electrically conductive foam element electrically contacts the planar metal surface section at least partially. Such configuration is especially advantageous if the planar metal surface is configured to be a part of the housing of the printed circuit board unit.

The grounded element of the printed circuit boarded electrically contacted by the front side is a planar metal surface section. Such planar metal surface section can be easily provided as part of the housing of the printed circuit board. The grounded planar metal surface section is electrically isolated from the inner conductor by a surface section opening. Through that surface section opening the inner conductor is guided, respectively connected, with a trace of the printed circuit board, whereas the trace is configured to receive the signal from the inner conductor.

The outer conductor is electrically connected via the hollow-cylindrically shaped, electrically conductive foam element with the grounded element of the printed circuit board unit by the front side of the hollow-cylindrically shaped electrically conductive foam element. The frontside is preferably pressed on the planar metal surface. This is especially of advantage if the front side of the hollow-cylindrically shaped electrically conductive foam element and the planar metal surface are configured co-planar, i.e., also the front side is planar and parallel to metal surface. This means the contact forces act perpendicular on the contact area of the electrically conductive foam element and the grounded element creating an ideal setting for a good electrical connection.

In a further embodiment, which can be combined with all other embodiments of the RF connector assembly mentioned above or below, the grounded element may be configured as metalized edge of the printed circuit board and/or as housing of the printed circuit board unit. In a specific embodiment the outer conductor can also be connected to several different grounded elements via the electrically conductive foam element, e.g., a planar metal surface of a housing and the metalized edge of the printed circuit board. Using a grounded metalized edge, respectively a grounded edge metallization, whereas these terms are used synonymously in this patent application, of the printed circuit board is of specific advantage. It realizes an easy constructive solution to connect the outer conductor with the grounded element via the electrically conductive foam element. This enables the shortest possible connection between the coaxial RF connector and the printed circuit board.

In a further embodiment, which can be combined with all other embodiments of the RF connector assembly mentioned above or below, the metalized edge of the printed circuit board may be galvanically interrupted, whereas the galvanic interruption is configured such that a lateral distance of at least one diameter, especially at most four diameters, is given from the inner conductor to the adjacent metalized edge.

Galvanic interruption shall mean that no metalized layer in the area of the galvanic interruption is present in which a current can flow. Lateral distance shall mean the shortest projected distance (as the edge metallization and the inner conductor are on different height levels) between the respective edge of the galvanic interruption and the inner conductor in a plane parallel to the plane of the printed circuit board on which the inner conductor is connected to the printed circuit board.

Practically, such galvanic interruption can be realized by removing the metalized edge of the printed circuit board in the area defined as galvanic interruption. The area, in which the galvanic interruption is present, e.g., in which the metallization is removed, comprises at least a width of two diameters of the inner conductor; further it is preferable, if the width of the galvanic interruption is at most 6 diameters of the inner conductor.

Preferably, the inner conductor is positioned symmetrically, i.e., centrally, within the width range in lateral direction. The width of the galvanic interruption should be sufficiently large to avoid electric influence of the inner conductor by the residual metalized edge, i.e., the grounded element, but sufficiently small to allow a large contact area of the electrically conductive foam element, especially its front side, with residual edge metallization of the printed circuit board.

In a further embodiment, which can be combined with all other embodiments of the RF connector assembly mentioned above or below, the coaxial RF connector may be configured as edge connector of the printed circuit board. As the challenges regarding the low-induction reverse currents in HF applications occur at the edge connectors of the printed circuit board, this is an advantageous field of application of the respective teaching.

In a further embodiment of the measurement application device, which can be combined with all other embodiments of the RF connector assembly mentioned above and below, such measurement application devices may comprise a switching unit for a measurement application to switch between a first switching state and a second switching state, whereas in the first switching state the device is configured to operate signals with an input impedance between 20 to 100 Ohm and the second switching state the device is configured to operate signals with an input impedance of 1 MOhm or more, whereas in both switching states the signals are transmittable via the same RF connector assembly. This allows to reduce the complexity of such measurement application device as fewer connectors are necessary for the printed circuit board to perform the same functionalities.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows schematic sectional side view in an axial plane P′ of a first embodiment of a part of the RF connector assembly according to the disclosure,

FIG. 2 shows schematic sectional side view in an axial plane P′ of a second embodiment of a part of the RF connector assembly according to the disclosure,

FIG. 3 shows a schematic sectional front view of an embodiment of a RF connector assembly in a plane P perpendicular to the axial plane P′ according to the disclosure,

FIG. 4 shows a schematic top sectional view on an embodiment of a part of a RF connector assembly according to the disclosure,

FIG. 5 shows a schematic view of an oscilloscope utilizing a RF connector assembly according to an embodiment of the invention,

FIG. 6 shows a functional view of an oscilloscope utilizing a RF connector assembly,

FIG. 7 shows a schematic flow chart for an exemplary embodiment relating to the manufacturing of an RF connector assembly according to the disclosure.

In the figures like reference signs denote like elements unless stated otherwise.

### DETAILED DESCRIPTION OF THE DRAWINGS

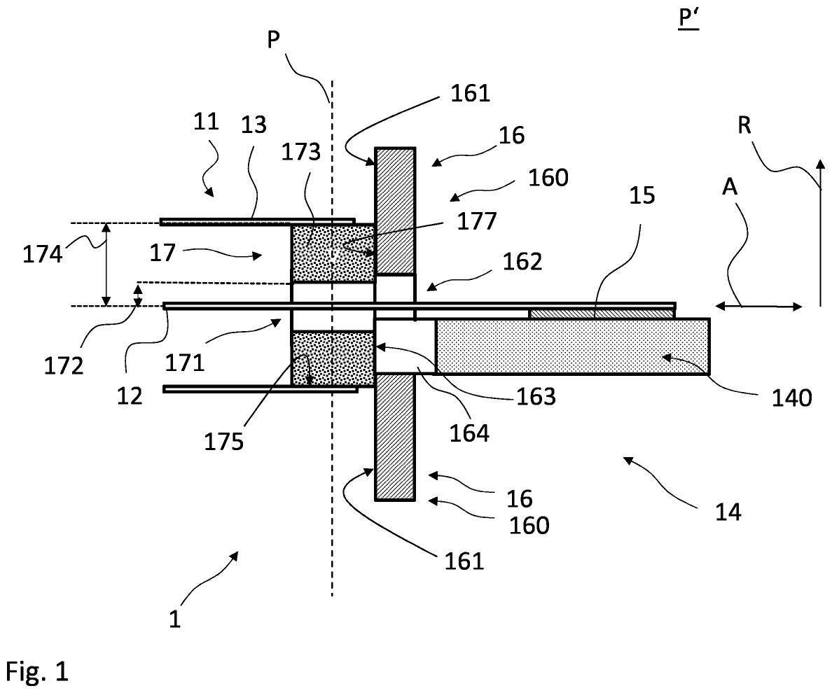

FIG. 1 shows a schematic sectional side view in an axial plane P′ of a first embodiment of a part of a RF connector assembly 1. Such RF connector assembly 1 can preferably be used for high precision measurement application devices, like oscilloscopes.

The RF connector assembly 1 comprises a coaxial RF connector 11, which comprises an inner conductor 12 and an outer conductor 13, both extending in axial direction A. The outer conductor 13 is arranged tubular and concentrically around the inner conductor 12 in axial direction A. Further, the outer conductor 13 is distanced in radial direction R from the inner conductor 12. An electrical isolating material can be present between the inner conductor 12 and the outer conductor 13, which is not shown.

FIG. 1 further shows a printed circuit board unit 14, comprising a printed circuit board 140 and other components, e.g., housing elements housing the printed circuit board 140. The inner conductor 12 is connected with the printed circuit board 140. Therefore, the inner conductor 12 extends from the coaxial RF connector 11 to a trace connector 15 comprised by the printed circuit board 140. The trace connector 15 allows to exchange the input signal between the inner conductor 12 and the printed circuit board 140. The coaxial RF connector 11 is configured as edge connector for the printed circuit board 140, i.e., a connector receiving or providing a signal from or to an external electric apparatus.

The inner conductor 12 can carry a measurement application signal. This measurement application signal can be an input signal or an output signal. In the following, the further disclosure is made for input signals, i.e., signals running from the coaxial RF connector 11 to the printed circuit board unit 14. However, it is evident for the skilled person, that the made disclosure can also be applied for output signals, i.e., signals running from the printed circuit board unit 14 to the coaxial RF connector 11.

The printed circuit board 140 is configured to perform desired applications, especially measurement applications, e.g., high frequency signal analysis. The printed circuit board therefore comprises a plurality of electrical elements and conductive layers performing the desired application.

To avoid disturbances of the signal processing, the printed circuit board unit comprises typically a plurality of grounded elements 16, which can e.g., be housing elements 160 of the printed circuit board unit 14 or grounded electrical elements or layers comprised by the printed circuit board 140. These grounded elements 16 are of relevance for the reverse current flowing back from the printed circuit board 14 to the outer conductor 13 of the coaxial RF connector 11.

The reverse current exchanged via the grounded elements 16 of the printed circuit board unit 14 back to the coaxial RF connector 11, especially to the outer conductor 13, can cause challenges especially in case the current is of high frequencies, e.g., 8 GHz, 12 GHz or above, especially 15 GHz or above. In this regard simulations showed that the reverse current connection of the printed circuit board unit 14 and the coaxial RF connector is of high importance.

Especially for high frequencies a low inductivity needs to be assured. Further a controlled impedance must be present between the coaxial RF connector 11 and the printed circuit board unit 14 to avoid undesired effects, e.g., reflections.

Also, a sufficiently good electrical connection of the one or more grounded element 16 of the printed circuit board unit 14 and the outer conductor 13 of the coaxial RF connector 11 is required as otherwise this can negatively influence the bandwidth of the connection. Such electrical connection can be influenced by technical tolerances during the manufacturing process of electrical elements leading to deviations in the mechanical dimensions of the coaxial RF connector 11 and the printed circuit board unit 14. This means that such technical mechanical tolerances are suitable to adversely affect the reverse current flow, if no sufficiently good electrical connection is established.

The challenges described above can be overcome by arranging an electrically conductive foam element 17 in radial direction R between the inner conductor 12 and the outer conductor 13. This electrically conductive foam element 17 further extends in axial direction A towards at least one grounded element 16 of the printed circuit board unit 14. The electrically conductive foam element 17 is configured such that it electrically connects the outer conductor 13 and the at least one grounded element 16. However, the electrically conductive foam element 17 is configured such that there the electrically conductive foam is electrically isolated from the inner conductor 12.

The electrical isolation of the electrically conductive foam element 17 from the inner conductor 12 can be realized by providing an opening 171 as part of the electrically conductive foam element 17. The opening 171 is configured to be concentrically arranged around the inner conductor 12 and has an opening radius 172, which is significantly larger than the outer radius of the inner conductor 12. This realizes an air gap between the electrically conductive foam and the inner conductor 12.

In FIG. 1 the electrically conductive foam element 17 is of hollow-cylindric shape comprising the opening 171 and a cylinder wall 173 comprising the electrically conductive foam, both extending in axial direction A. The cylinder wall 173 has a thickness which is given by the difference of the outer radius 174 of the cylinder wall 173 and the radius 172 of the opening 171 of the electrically conductive foam element 17, corresponding to the inner radius of the cylinder wall 173.

In FIG. 1 an outer radius 174 of the hollow-cylindric shaped electrically conductive foam element 17 has a constant radius. According to FIG. 1 the outer radius 174 of the cylindric wall 173 corresponds to the inner radius of the outer conductor 13, especially in the installed state. This means that significant parts of an outer surface 175 of the cylinder all 173 are in electrical contact with the radially inner surface of the outer conductor 13, especially in axial and circumferential direction.

Before the electrically conductive foam element 17 is inserted into the coaxial RF connector 11, the outer radius of the cylinder wall can be slightly larger than the inner radius of the outer conductor 13 enabling a press fitted arrangement of the electrically conductive foam element 17 within the volume defined by the outer conductor 13.

A part of the of the electrically conductive foam element 17 protrudes the outer conductor 13 in axial direction A towards the grounded elements 16. The side of the electrically conductive foam element 17 oriented towards the grounded elements 16 is the front side 177 of the electrically conductive foam element 17. This front side 177 electrically contacts the grounded elements 16.

In FIG. 1 several grounded elements 16 are shown. The grounded elements 16 comprise housing elements 160 of the printed circuit board unit 14, which house the printed circuit board 140. The housing elements 160 are arranged radially distant from the inner conductor 12, i.e., are electrically isolated from the inner conductor 12. These housing elements 160 comprise a planar metal surface 161 which is in electrical contact with the front side 177 of the electrically conductive foam element 17.

By utilizing an electrically conductive foam element 17 which is configured to be compressible, especially elastically compressible, at typical pressure forces used to fix a coaxial RF connector 11 on a printed circuit board unit 14, the electrically conductive foam element 17 can compensate mechanical tolerances of the coaxial RF connector 11 and the printed circuit board unit 14 and establish a proper electrical connection between the grounded elements 16 and the outer conductor 13.

In addition, the front side 177 of the electrically conductive foam element 17 is in electrical contact with a grounded element configured as grounded edge metallization 163 of the printed circuit board 140. The edge metallization 163 has a planar section. However, below the inner conductor the edge metallization 163 is galvanically interrupted in a certain area, e.g., there is a metallization gap 164 of the edge metallization 163.

The metallization gap 164 can be reached e.g., by removing the edge metallization 163 from the edge of the printed circuit board 140 before the coaxial RF connector is attached, or the metallization gap 164 of the metalized edge 163 of the printed circuit board 140 is already considered during the manufacturing process of the printed circuit board 140.

With the shown embodiment a low-inductive grounded connection between coaxial RF connector 11 and printed circuit board unit 14 can be achieved, providing a controlled impedance whereas mechanical tolerances can be effectively compensated.

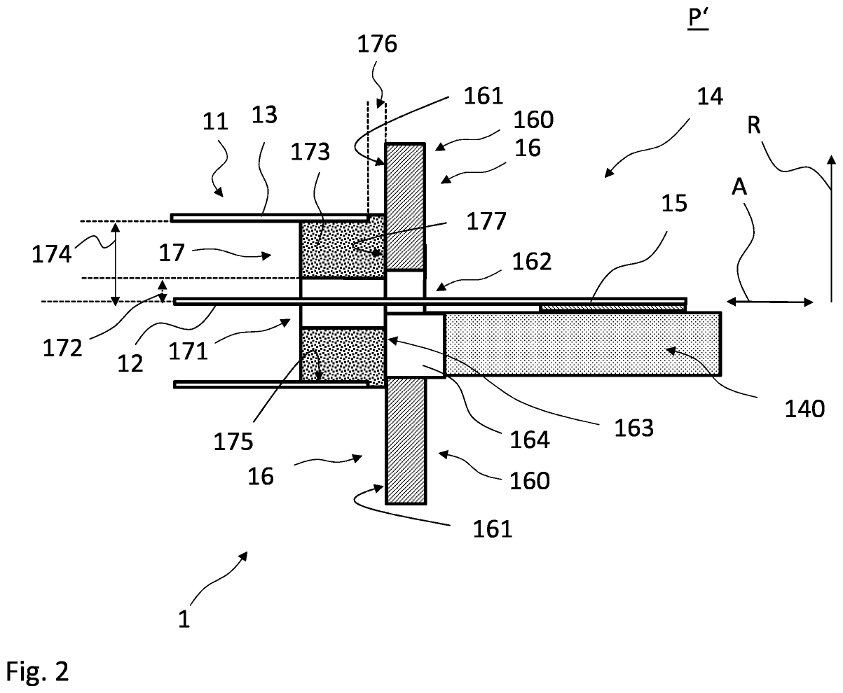

FIG. 2 shows an embodiment according to FIG. 1 with a modified form of the electrically conductive foam element 17. According to the embodiment of FIG. 2 the electrically conductive foam element 17 is also hollow-cylindrically shaped, however the outer radius 174 of the cylinder wall 173 is not constant in axial direction A.

To the extent the electrically conductive foam element 17 is inserted, respectively pressed, into the volume defined by the outer conductor 13, the outer radius 174 of the cylinder wall 173 corresponds again to the inner radius of the outer conductor 13.

However, a protruding part 176 of the cylinder wall 173 arranged in axial direction A between the outer conductor 13 and the grounded elements 16, has an outer radius 174 corresponding to, respectively matching, the outer radius of the outer conductor 13. This means, that protruding part 176 of the cylindric wall 173 is flush with the outer conductor and does not exceed the outer radius of the outer connector 13 in radial direction R, which in other embodiments is also possible.

Such change in the outer radius 174 of the cylinder wall 173, respectively the outer radius of the electrically conductive foam element 17, allows in axial direction A an easy installation of the electrically conductive foam element 17, even manually, as the part of the electrically conductive foam element 17 to be arranged in the volume defined by the outer conductor 13 and the protruding part 176 are each defined by its different radius. By such configuration an insertion stop is defined for the electrically conductive foam element 17. This is also mechanically of advantage in terms of maintenance as no recess between the outer conductor 13 and the planar surface section 161 of the housing 160 is present. This reduces the exposure to and collection of dirt particles.

In addition, the length of the electrically conductive foam element 17 in axial direction A can be optimized. Due to the insertion stop defined boundary conditions are determined regarding the axial length of the electrically conductive foam element 17 inserted into the volume defined by the outer conductor 13 and the axial length of the electrically conductive foam element 17 protruding the outer conductor 13.

The protruding part 176 of the electrically conductive foam element 17 is preferably configured such, especially having a respective length in axial direction A, that it is suitable to compensate the technical tolerances given by the coaxial RF connector 11 and the grounded elements 16 of the printed circuit board unit 14 in axial direction A. The part of the electrically conductive foam element 17 arranged radially between the inner conductor 12 and the outer conductor 13, is preferably configured to compensate the technical tolerances given by the coaxial RF connector 11 in radial direction R.

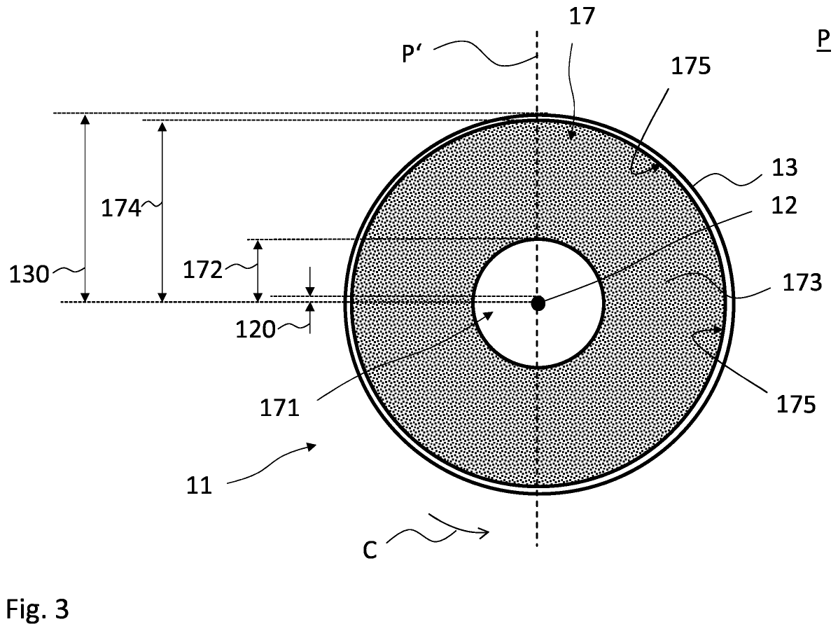

FIG. 3 shows a cross-sectional view of the coaxial RF connector 11 with the electrically conductive foam element 17 in a plane P, which is shown in FIG. 1. In this plane P the electrically conductive foam element 17 is arranged in radial direction between the inner conductor 12 and the outer conductor 13.

The inner conductor 12 is arranged concentrically around the center axis of the coaxial RF connector 11, whereas the center axis is not shown. Further the outer conductor 13 is arranged concentrically around the inner conductor 12. Between the outer conductor 13 and the inner conductor 12 the electrically conductive foam element 17 is arranged.

The electrically conductive foam element 17 comprises as a first part, a cylinder wall 173, which is of a ring-like shape in plane P. According to FIG. 3, the cylinder wall 173 consists entirely of the electrically conductive foam. This is however only an advantageous alternative. The cylinder wall 173 can e.g., also comprise a solid isolating material radially arranged between the inner conductor 12 and the electrically conductive foam. In such case the solid isolation material would be part of the cylinder wall 173. The isolating material can also contact the outer radius 120 of the inner conductor 12. In this specific case, i.e., if a gap between the solid isolating material and the outer radius of the inner conductor 12 is not present, such configuration is mechanically more stable, as the inner conductor 1 is mechanically fixed in its axial position by the solid isolating material. However, such solution is more expensive and might be considered only in certain applications in which a mechanical stabilization of the inner conductor 12 is considered appropriate.

According to the FIG. 3 the electrically conductive foam element 17 comprises an axially concentrically arranged circular opening 171. The inner conductor 12 is fed centrally through this opening 171 in direction to the printed circuit board unit, i.e., in axial direction.

The inner conductor 12 has an outer radius 120. The opening 171 has a radius 172. The cylinder wall 173 has a thickness, in the installed state, in radial direction given by its outer radius 174 minus the opening radius 172. In the installed state the outer radius 174 of the cylinder wall 173 corresponds to the inner radius of the outer conductor 13. This means that the outer surface 175 of the cylinder wall is ideally in 360° in the shown plane P in electrical contact with the inner surface of the outer conductor 13. In other words, an electrical contact between the cylinder wall 173 and the outer conductor 13 is not only established in axial direction but also in circumferential direction C. The outer conductor 13 is of an outer radius 130.

In the un-installed state, the cylinder wall 173 can have an outer radius 174 that is slightly larger than the inner radius of the outer conductor 13 to allow an installation of the electrically conductive foam element 17 by press fitting into the volume enclosed by the outer conductor 13.

According to FIG. 3 the thickness of the cylinder wall 173, especially of the electrically conductive foam, is roughly 65% of the radial distance of the outer radius 172 of the inner conductor 12 and the inner radius of the outer conductor 13, respectively of the outer radius 174 of the cylinder wall 173 in the installed state. The thickness share of the electrically conductive foam in radial distance is preferably between 40% and 85% of the radial distance of the outer radius 172 of the inner conductor 12 and the inner radius of the outer conductor 13, respectively of the outer radius 174 of the cylinder wall 173 in the installed state.

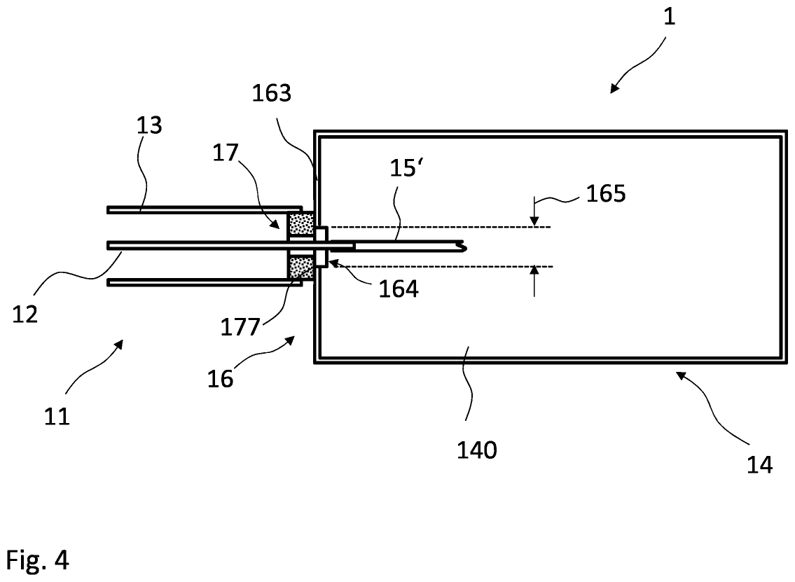

FIG. 4 shows a schematic top sectional view on a relevant part of the RF connector assembly 1. On the left side the coaxial RF connector 11 is shown comprising the inner conductor 12 and the outer conductor 13. The inner conductor 12 extends to the printed circuit board unit 14 and contacts a trace 15′.

The printed circuit board unit 14 comprises a printed circuit board 140. The printed circuit board 140 comprises a grounded element 16, which is configured as edge metallization 163, respectively metalized edge 163, of the printed circuit board 140. The edge metallization 163 is a metallic layer extending in circumferential direction along the thinnest side of the three sides of the printed circuit board 140. This is schematically shown in FIG. 3 by a respective metallization layer, which is in practice comparably thin, i.e., the physical dimensions of the thickness of the metallization edge 163 in FIG. 3 do not reflect an actual thickness in practice. This metallization edge 163 is on ground potential.

The metalized edge 163 is configured to be essentially planar allowing, to the extent it is oriented towards the coaxial RF connector 11, that the edge metallization 163 runs essentially parallel to the front side 177 of the electrically conductive foam element 17.

Further FIG. 4 shows, as already indicated in the description of FIG. 1, that the edge metallization 163 is laterally distanced to the inner conductor 12. In FIG. 4 the lateral distance corresponds in FIG. 3 to the upside and downside direction in the sheet plane, defining a width 165 of the galvanic interruption 164. This area is free of metallization and provides the galvanic interruption 164 of the edge metallization 163.

The width 165 of the galvanic interruption 164 is preferably configured such that it has lateral extension of at least two diameters of the inner conductor 12, preferably three or four diameters, whereas the inner conductor 12 is arranged in the center of the galvanic interruption 164. The galvanic interruption can preferably have a width of 2 to 6 diameters of the inner conductor 12. This assures that on the one side the metallization edge is laterally sufficiently distant from the inner conductor 12 and on the other side the front side 177 of the electrically conductive foam element 17 can still contact the remaining metallization edge 163.

Any easy way to create the galvanic interruption 164 is to remove the edge metallization 163 in the respective area from the edge of the printed circuit board 140, whereas the area can be defined by the width 165 of the galvanic interruption and the thickness of the printed circuit board 140. The removal of the edge metallization 163 in that area can be achieved e.g., by cutting or milling the printed circuit board at the respective area or by etching the metal layer in the respective area until no metal of the edge metallization 163 is left and a galvanic interruption 164 of desired width 165 is accordingly created.

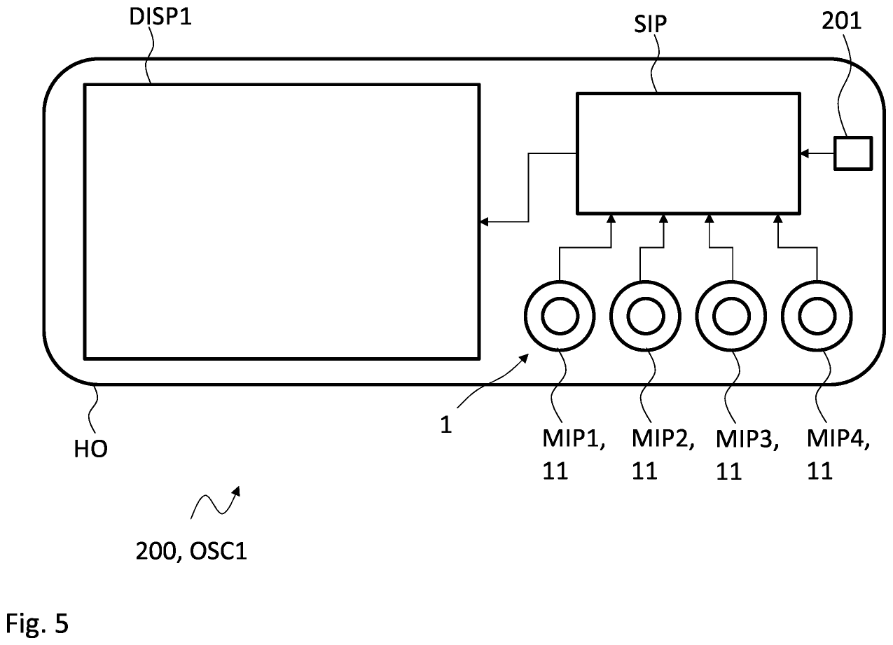

FIG. 5 shows a schematic block diagram of an oscilloscope OSC1, as an example of a measurement application device 200, that may be used with an RF connector assembly according to the present disclosure.

The oscilloscope OSC1 comprises a housing HO that accommodates four measurement inputs MIP1, MIP2, MIP3, MIP4 that are coupled to a signal processor SIP for processing any measured signals.

Each of the measurement inputs MIP1, MIP2, MIP3, MIP4 can be configured as RF connector assembly 1, from which the coaxial RF connector 11 is shown from a user perspective. The signal processor SIP is coupled to a display DISP1 for displaying the measured signals to a user.

The oscilloscope OSC1 comprises a switching unit 201, which provides the possibility to switch the operation of the signal processor SIP between high frequency applications and low frequency applications whereas the signal is transmitted via the same RF connector assembly.

E.g., in the first switching state the oscilloscope OSC1 is configured to operate signals with an input impedance between 20 to 100 Ohm, especially 50 to 80 Ohm, and in the second switching state the device is configured to operate signals with an input impedance of 1 MOhm or more, whereas in both switching states the signals are transmittable via the same RF connector assembly, e.g., the same measurement input. For avoidance of doubt, the terms “first” and “second” do not constitute an order, prioritization or the like. These terms are only used to distinguish between the two states.

Although not explicitly shown, it is understood, that the oscilloscope OSC1 may also comprise signal outputs that may also be coupled to the differential measurement probe. Also, this signal outputs can comprise an RF connector assembly as presented in this patent application.

Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

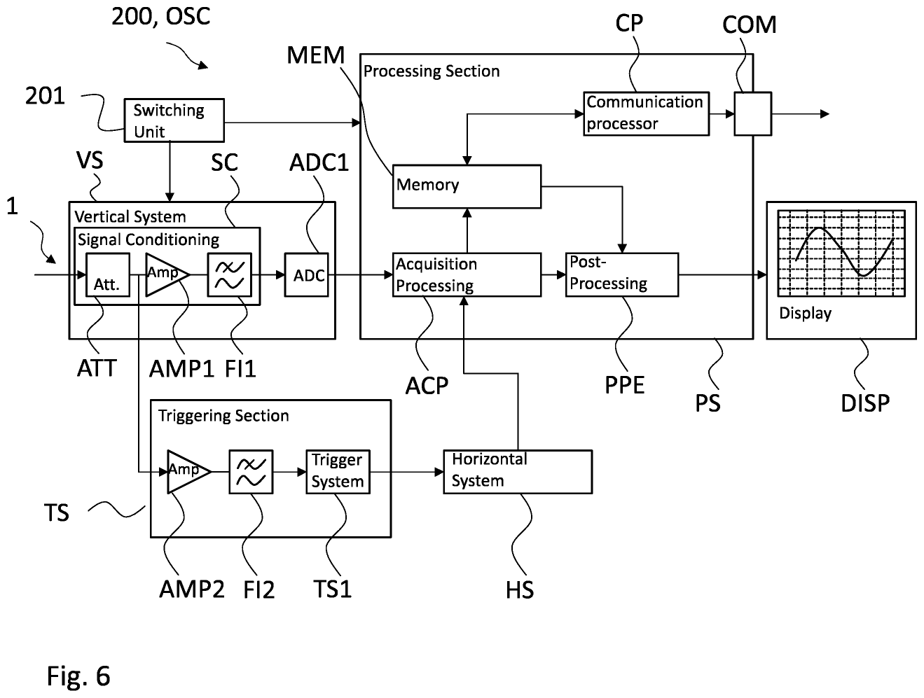

FIG. 6 shows a block diagram of an oscilloscope OSC that may be an implementation of a measurement application device 200. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS and the display DISP. It is understood that the partitioning into five general sections is a logical partitioning and does not limit the placement and implementation of any of the elements of the oscilloscope OSC in any way.

The vertical system VS mainly serves for attenuating or amplifying a signal to be acquired. Such signal can be received via a RF connector assembly 1 according to the disclosure. The signal may for example be modified to fit the signal in the available space on the display DISP or to comprise a vertical size as configured by a user.

To this end, the vertical system VS comprises a signal conditioning section SC with an attenuator ATT that is coupled to an amplifier AMP1. The amplifier AMP1 is coupled to a filter FI1, which in the shown example is provided as a low pass filter. The vertical system VS also comprises an analog-to-digital converter ADC1 that receives the output from the filter FI1 and converts the received analog signal into a digital signal.

The attenuator ATT and the amplifier AMP1 serve to scale the waveform of the signal and to condition the amplitude of the signal to be acquired to match the operation range of the analog-to-digital converter ADC1. The filter FI1 serves to filter out unwanted high frequency components of the signal to be acquired.

The triggering section TS comprises an amplifier AMP2 that is coupled to a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

The triggering section TS operates on the signal as provided by the attenuator ATT, which is fed into the amplifier AMP2. The amplifier AMP2 serves to condition the input signal to the operating range of the trigger system TS1. It is understood that a common amplifier may also be used instead of the dedicated amplifiers AMP1 and AMP2.

In order to allow an exact matching of the trigger event and the waveform that is shown on the display DISP, a common time base may be provided for the analog-to-digital converter ADC1 and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the attenuator ATT but will operate on the digital signal as provided by the analog-to-digital converter ADC1.

A digital triggering section may comprise a processing element, like a processor, a DSP, a CPLD or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC1 and the output of the horizontal system HS as well as to a memory MEM and a post processing element PPE.

A switching unit 201 allowing to use the same measurement input for high frequency and low frequency is connected to the vertical system VS and the processing section PS. This enables to oscilloscope OSC to adapt the operation on incoming high frequency or low frequency signals via the same measurement input.

The acquisition processing element ACP manages the acquisition of digital data from the analog-to-digital converter ADC1 and the storage of the data in the memory MEM. The acquisition processing element ACP may for example comprise a processing element with a digital interface to the analog-to-digital converter ADC1 and a digital interface to the memory MEM. The processing element may for example comprise a microcontroller, a DSP, a CPLD or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

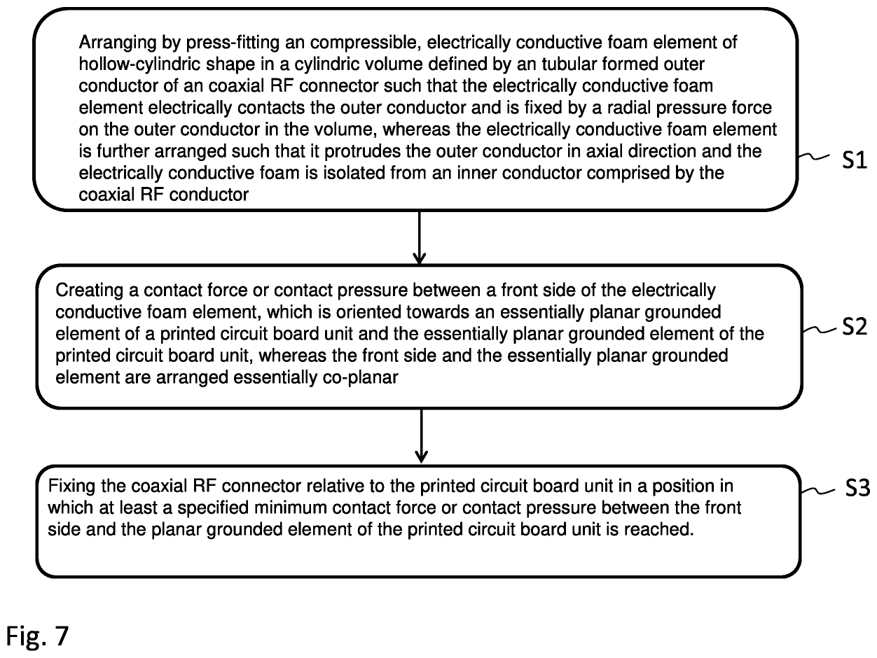

FIG. 7 shows a schematic flow diagram for manufacturing an exemplary RF connector assembly. In first a step S1 an elastically compressible, electrically conductive foam element is arranged in the cylindric volume defined by the outer conductor of the coaxial RF connector.

Such arrangement is realized by pressing the electrically conductive foam element in radial direction. After insertion of the elastically compressible electrically conductive foam element into the cylindric volume a press fitting is realized fixing the electrically conductive foam element in the outer conductor by radially pressing the outer surface of cylinder wall of the electrically conductive foam element against the inner surface of the outer conductor.

In addition, an electric connection is established between the outer conductor and the electrically conductive foam element. An electrically conductive foam element of hollow-cylindric shape is used, which extends in axial direction beyond the outer conductor, i.e., has a protruding part in the installed state.

In addition, the hollow space is arranged such that the inner conductor of the coaxial RF connector is arranged centrally in the hollow space, i.e., radially and axially equally distanced to the electrically conductive foam. So, the inner conductor isolated from the electric foam.

In a second step S2 the coaxial RF connector is pressed towards several grounded elements of the printed circuit board unit. In this embodiment the printed circuit board unit comprises two first, essentially planar grounded elements and a second essentially planar grounded element. The first essentially planar grounded elements are part of a housing comprised by the printed circuit board unit. The second, essentially planar grounded element is a metalized edge of the printed circuit board.

To reach a good electrical connection, the first and second essentially planar grounded element each comprise a planar surface section which is arranged in the same plane. This means, a co-planar oriented front side of the electrically conductive foam element, will contact the first and the second grounded element at the same time when approached, and both essentially planar sections of the first and second grounded element will be exposed to the same pressure, respectively to same contact force.

As part of the second step S2 the contact force or contact pressure is applied pressing the front side of the electrically conductive foam element on the planar surface of first and second grounded element arranged in the same plane perpendicular to the pressure force.

In the third step S3 the coaxial RF connector is fixed relative to the printed circuit board unit in a position in which at least a specified minimum contact force or contact pressure between the front side and the planar grounded element of the printed circuit board unit is reached.

Reaching a defined contact pressure or contact force can also be assumed, if a certain contact force or contact pressure is applied to the configuration of coaxial RF connector and printed circuit board unit from an outer system which has proven to provide a reliable electric connection of the electrically conductive foam element and the grounded element of the printed circuit board unit.

Fixing the connection of the coaxial RF connector and the printed circuit board unit under such defined conditions provides a secure and reliable connection between the grounded elements of the printed circuit board unit and the electrically conductive foam element, which leads to the advantages of the RF connector assembly described above. For fixing the coaxial RF connector relative to the printed circuit board typical fixing means can be used, known to the person skilled in the art.

Although specific embodiments have been illustrated and described herein, it will be appreciated by those of ordinary skill in the art that a variety of alternate and/or equivalent implementations exist. It should be appreciated that the exemplary embodiment or exemplary embodiments are only examples, and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elements described in an exemplary embodiment without departing from the scope as set forth in the appended claims and their legal equivalents. Generally, this application is intended to cover any adaptations or variations of the specific embodiments discussed herein.

### LIST OF REFERENCE SIGNS

1 RF connector assembly
11 coaxial RF connector
12 inner conductor
13 outer conductor
14 printed circuit board unit
15 trace connector of the printed circuit board
15′ trace
16 grounded element of the printed circuit board
17 foam element: electrically conductive; having hollow-cylindric shape
120 outer radius of the inner conductor
130 outer radius of the outer conductor
140 printed circuit board
160 housing element
161 planar metal surface section, grounded, housing
162 surface section opening
163 metalized edge of the printed circuit board/edge metallization
164 galvanic interruption of metalized edge: metallization gap
165 Width of galvanic interruption
171 first part: opening of the foam element: circular
172 radius of the opening, identical to radius inner wall
173 second part: cylinder wall comprising electrically conductive foam
174 outer radius of the cylinder wall
175 radial outer surface of the cylinder wall
176 protruding part of the foam element arranged between outer conductor and grounded element in axial direction
177 front side of the foam element
200 Measurement application device: oscilloscope
201 Switching unit radial direction
A axial direction
P plane, perpendicular to the axial direction
P′ central plane in axial direction
C circumferential direction
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
AMP1 amplifier
FI1 filter
ADC1 analog-to-digital converter
TS triggering section
AMP2 amplifier
FI2 filter
TS1 trigger system
HS horizontal system
PS processing section
ACP acquisition processing element
MEM memory
PPE post processing element
DISP display

1. An RF connector assembly, comprising:
a coaxial RF connector, wherein the coaxial RF connector comprises an axially arranged inner conductor and a tubular outer conductor radially enclosing the inner conductor in an axial direction;
a printed circuit board unit comprising a printed circuit board to which the coaxial RF connector is electrically connected for transmitting signals between the coaxial RF connector and the printed circuit board;
a trace of the printed circuit board to which the inner conductor is electrically connected and a grounded element comprised by the printed circuit board unit to which the outer conductor is electrically connected; and
an electrically conductive foam element arranged radially between the inner conductor and the outer conductor, wherein the electrically conductive foam element extends in the axial direction towards the grounded element, wherein the electrically conductive foam element is configured such that it electrically connects the outer conductor and the grounded element and is electrically isolated from the inner conductor.

2. The RF connector assembly according to claim 1, wherein the electrically conductive foam element comprises:
a first part comprising an opening in a plane perpendicular to the axial direction, through which the inner conductor is guided in the axial direction; and
a second part comprising electrically conductive foam, wherein the opening is configured such that the electrically conductive foam is arranged radially distant from the inner conductor.

3. The RF connector assembly according to claim 2, wherein the electrically conductive foam element is compressible in the axial direction and/or radial direction, especially elastically compressible.

4. The RF connector assembly according to claim 2, wherein the electrically conductive foam element is of a hollow-cylindric shape providing, in radial direction, the opening and a cylinder wall comprising electrically conductive foam, wherein the electrically conductive foam, especially comprised by a surface of the wall directed to the outer conductor, electrically contacts the outer conductor.

5. The RF connector assembly according to claim 3, wherein the electrically conductive foam element is of a hollow-cylindric shape providing, in radial direction, the opening and a cylinder wall comprising electrically conductive foam, wherein the electrically conductive foam, especially comprised by a surface of the wall directed to the outer conductor, electrically contacts the outer conductor.

6. The RF connector assembly according to claim 4, wherein the electrically conductive foam element electrically contacts the grounded element with a front side of the hollow-cylindric shaped electrically conductive foam element, which front side is oriented towards the grounded element.

7. The RF connector assembly according to claim 5, wherein the electrically conductive foam element electrically contacts the grounded element with a front side of the hollow-cylindric shaped electrically conductive foam element, which front side is oriented towards the grounded element.

8. The RF connector assembly according to claim 7, wherein the cylinder wall has a radial thickness smaller than 0.9*((inner radius of the outer conductor)— (outer radius of the inner conductor)) but at least 0.2*((inner radius of the outer conductor)— (outer radius of the inner conductor)).

9. The RF connector assembly according to claim 7, wherein the electrically conductive foam element comprises a protruding part which is arranged in the axial direction between the outer conductor and the grounded element.

10. The RF connector assembly according to claim 8, wherein the electrically conductive foam element comprises a protruding part which is arranged in the axial direction between the outer conductor and the grounded element.

11. The RF connector assembly according to claim 7, wherein the grounded element comprises a planar metal surface section with a surface section opening, wherein the inner conductor is guided through that surface section opening to the trace and is electrically isolated from the metal surface, wherein the front side of the hollow-cylindrically shaped electrically conductive foam element electrically contacts the planar metal surface section at least partially.

12. The RF connector assembly according to claim 10, wherein the grounded element comprises a planar metal surface section with a surface section opening, wherein the inner conductor is guided through that surface section opening to the trace and is electrically isolated from the metal surface, wherein the front side of the hollow-cylindrically shaped electrically conductive foam element electrically contacts the planar metal surface section at least partially.

13. The RF connector assembly according to claim 7, wherein the grounded element is configured as metalized edge of the printed circuit board.

14. The RF connector assembly according to claim 10, wherein the grounded element is configured as metalized edge of the printed circuit board and/or as housing of the printed circuit board unit.

15. The RF connector assembly according to claim 14, wherein the metalized edge of the printed circuit board is galvanically interrupted, wherein the galvanic interruption is configured such that a lateral distance of at least one diameter, especially at most four diameters, is given from the inner conductor to the adjacent metalized edge.

16. The RF connector assembly according to claim 10, wherein the electrically conductive foam element is non-removably arranged, especially by press fitting, or removably arranged in a volume enclosed by the outer conductor.

17. The RF connector assembly according to claim 1, wherein the coaxial RF connector is configured as an edge connector of the printed circuit board.

18. A measurement application device comprising at least one RF connector assembly, comprising:
a coaxial RF connector, wherein the coaxial RF connector comprises an axially arranged inner conductor and a tubular outer conductor radially enclosing the inner conductor in an axial direction;
a printed circuit board unit comprising a printed circuit board to which the coaxial RF connector is electrically connected for transmitting signals between the coaxial RF connector and the printed circuit board;
a trace of the printed circuit board to which the inner conductor is electrically connected and a grounded element comprised by the printed circuit board unit to which the outer conductor is electrically connected; and
an electrically conductive foam element arranged radially between the inner conductor and the outer conductor, wherein the electrically conductive foam element extends in the axial direction towards the grounded element, wherein the electrically conductive foam element is configured such that it electrically connects the outer conductor and the grounded element and is electrically isolated from the inner conductor.

19. The measurement application device according to claim 18, comprising a switching unit for a measurement application to switch between a first switching state and a second switching state, wherein in the first switching state the device is configured to operate signals with an input impedance between 20 to 100 Ohm and in the second switching state the device is configured to operate signals with an input impedance of 1 MOhm or more, wherein in both switching states the signals are transmittable via the same RF connector assembly.

20. A method for manufacturing a RF connector assembly, comprising:
arranging by press-fitting a compressible, electrically conductive foam element of hollow-cylindric shape in a cylindric volume defined by a tubular formed outer conductor of a coaxial RF connector such that the electrically conductive foam element electrically contacts the outer conductor and is fixed by a radial pressure force on the outer conductor in the volume, wherein the electrically conductive foam element is further arranged such that it protrudes the outer conductor in axial direction and the electrically conductive foam element is isolated from an inner conductor comprised by the coaxial RF connector;
creating a contact force or contact pressure between a front side of the electrically conductive foam element, which is oriented towards an essentially planar grounded element of a printed circuit board unit and the essentially planar grounded element of the printed circuit board unit, wherein the front side and the essentially planar grounded element are arranged essentially co-planar; and
fixing the coaxial RF connector relative to the printed circuit board unit in a position in which at least a specified minimum contact force or contact pressure between the front side and the planar grounded element of the printed circuit board unit is reached.

21. The method according to claim 20, wherein the printed circuit board unit comprises at least a first, essentially planar grounded element and a second, essentially planar grounded element, wherein the first grounded element is part of a housing of the printed circuit board unit, wherein the second grounded element is a metalized edge of the printed circuit board, wherein the first and second grounded element each comprise a planar surface section arranged in the same plane, wherein the contact force or contact pressure is created by pressing the front side of the electrically conductive foam element on the first and second grounded element.
